(19) United States
(12) Patent Application Publication
(10) Pub. No.: US 2015/0262957 A1
(43) Pub. Date: Sep. 17, 2015

(54) SEMICONDUCTOR PACKAGE

(71) Applicant: Shinko Electric Industries Co., LTD., Nagano-ken (JP)

(72) Inventor: Yoshihiro Ihara, Nagano-Ken (JP)

(73) Assignee: Shinko Electric Industries Co., LTD., Nagano-ken (JP)

(21) Appl. No.: 14/638,188

(22) Filed: Mar. 4, 2015

(30) Foreign Application Priority Data
Mar. 11, 2014 (JP) 2014-047684

(51) Int. Cl. H01L 23/00

(52) U.S. Cl. CPC H01L 24/17; H01L 24/70; H01L 24/09; H01L 2224/02235

(57) ABSTRACT

A semiconductor package includes a wiring substrate including a first surface and a second surface that are opposed to each other, a plurality of mounting pads arranged on the first surface, and a plurality of connection pads arranged on the second surface, and a plurality of connection members respectively connected to the connection pads. Each of the connection members includes a holding member opposing the second surface of the wiring substrate, and a plurality of elastic and conductive connection terminals. Each of the connection terminals includes a first end and a second end. The first end is held by the holding member so that the first end is exposed from a surface of the holding member that is located at a side opposite to the wiring substrate. The second end is connected to a corresponding one of the connection pads.

### CROSS-REFERENCE TO RELATED APPLICATIONS

This application is based upon and claims the benefit of priority from prior Japanese Patent Application No. 2014-047684, filed on Mar. 11, 2014, the entire contents of which are incorporated herein by reference.

### FIELD

This disclosure relates to a semiconductor package.

### BACKGROUND

In the prior art, a semiconductor element is mounted on a package, such as a ball grid array (BGA) or a land grid array (LGA). Such a package is mounted on a substrate, such as a motherboard. A package is directly assembled to a substrate by solder. A package is also connected to a substrate by a connector or a socket (e.g., refer to Japanese Laid-Open Patent Publication No. 10-199641 and Japanese National Phase Laid-Open Patent Publication No. 2001-524258).

### SUMMARY

When a package is directly mounted on a substrate using lead-free solder, the substrate may warp and break connections. This may lower the connection reliability. When mounting a package onto a substrate using a socket or the like, the connection reliability may also decrease between the substrate and the socket.

In one aspect of this disclosure, a semiconductor package includes a wiring substrate including a first surface and a second surface that are opposed to each other, a plurality of mounting pads arranged on the first surface, and a plurality of connection pads arranged on the second surface, and a plurality of connection members respectively connected to the connection pads. Each of the connection members includes a holding member opposing the second surface of the wiring substrate, and a plurality of elastic and conductive connection terminals. Each of the connection terminals includes a first end and a second end. The first end is held by the holding member so that the first end is exposed from a surface of the holding member that is located at a side opposite to the wiring substrate. The second end is connected to a corresponding one of the connection pads.

Other aspects and advantages of the invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic cross-sectional diagram of a semiconductor device;

FIG. 2 is a schematic diagram illustrating a reverse surface of the semiconductor device;

FIG. 3 is a partial view of the reverse surface of the semiconductor device and illustrates the layout of holding members;

FIG. 4 is a perspective view of a connection terminal;

FIG. 5 is a perspective view of the holding member;

FIG. 6 is a cross-sectional view illustrating a manufacturing procedure;

FIGS. 7A and 7B are perspective views of the connection terminals in a manufacturing procedure;

FIG. 8 is a cross-sectional view illustrating a manufacturing procedure;

FIG. 9 is a schematic cross-sectional view illustrating another connection member;

FIG. 10 is a schematic cross-sectional view illustrating another connection member;

FIG. 11 is a schematic cross-sectional view illustrating another connection member;

FIG. 12 is a schematic cross-sectional view illustrating another connection member;

FIG. 13 is a perspective view illustrating another connection terminal;

FIG. 14A is a perspective view illustrating another connection terminal, and FIG. 14B is a side view of the connection terminal;

FIG. 15A is a perspective view illustrating another connection terminal, and FIG. 15B is a cross-sectional view of the connection terminal;

FIG. 16 is a perspective view illustrating another connection terminal; and

FIGS. 17A and 17B are perspective views illustrating other connection terminals.

### DESCRIPTION OF THE EMBODIMENTS

Each embodiment will now be described with reference to the accompanying drawings.

Elements in the drawings may be partially enlarged and thus have not necessarily been drawn to scale. In the cross-sectional views, hatching of some elements is omitted for clarity.

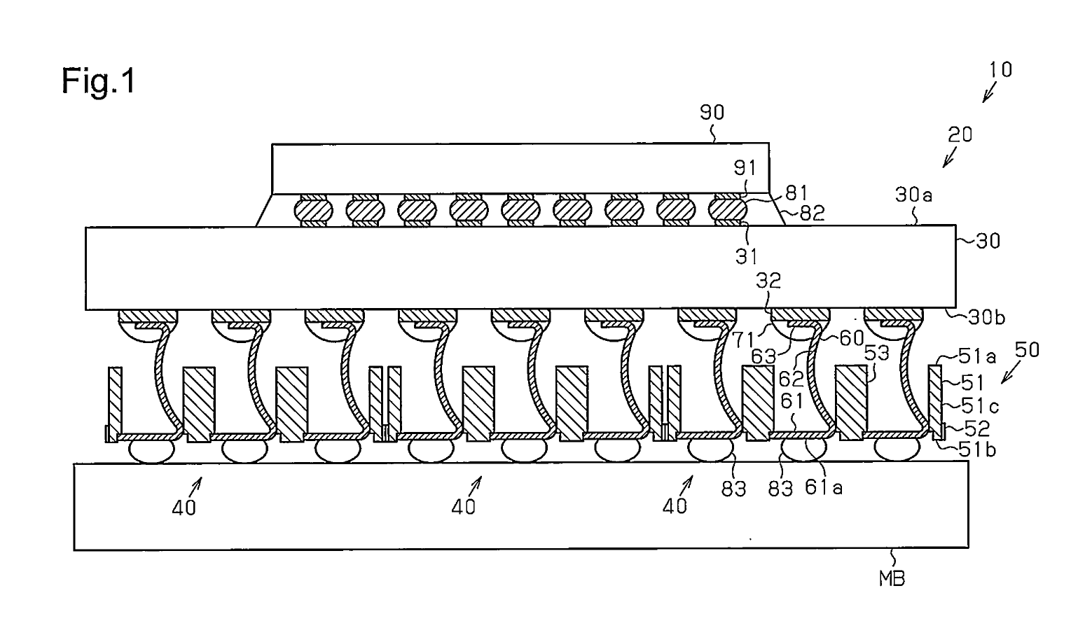

As illustrated in FIG. 1, a semiconductor device 10 is mounted on a first surface (upper surface as viewed in the drawing) of a motherboard MB.

The semiconductor device 10 includes a semiconductor package 20, which is connected to the motherboard MB, and a semiconductor element 90, which is mounted on the semiconductor package 20.

The semiconductor package 20 includes a wiring substrate 30 and a plurality of connection members 40. The wiring substrate 30 includes a first surface 30a (upper surface as viewed in the drawing) and a second surface 30b (lower surface as viewed in the drawing) that are opposed to each other. The semiconductor element 90 is mounted on the first surface 30a (upper surface in the drawing) of the wiring substrate 30. The connection members 40 are connected to the second surface 30b of the wiring substrate 30. The connection members 40 connect the wiring substrate 30 and the motherboard MB.

The first surface 30a (upper surface) of the wiring substrate 30 includes a plurality of mounting pads 31. A bump 81 connects each mounting pad 31 and one of a plurality of pads 91 on the semiconductor element 90. The wiring substrate 30, which is, for example, formed from an organic base material (organic substrate), includes fibers of glass or the like. The material of the mounting pads 31 may be, for example, copper (Cu), nickel (Ni), a nickel alloy, or the like. The bumps 81 may be, for example, solder bumps.

An underfill resin 82 fills a gap between the first surface 30a of the wiring substrate 30 and the semiconductor element 90. The underfill resin 82 includes a fillet, which gradually expands in a sloped manner from a lower portion of a side surface of the semiconductor element 90 to the first surface 30a of the wiring substrate 30. The underfill resin 82 increases the connection strength between the wiring substrate 30 and the semiconductor element 90 and limits corrosion or electromigration of the mounting pads 31 and the like. The material of the underfill resin 82 may be, for example, an insulative resin, such as an epoxy resin or a polyimide resin. Alternatively, the underfill resin 82 may be formed from a resin material in which a filler, such as silica or alumina, is mixed with an insulative resin, such as an epoxy resin or a polyimide resin.

The second surface 30b (lower surface) of the wiring substrate 30 includes a plurality of connection pads 32. The material of the connection pads 32 may be, for example, copper (Cu), nickel (Ni), a nickel alloy, or the like. The wiring substrate 30 electrically connects each mounting pad 31 of the first surface 30a and one of the connection pads 32 on the second surface 30b. A wiring layer may be formed in the wiring substrate 30, although such a wiring layer is not necessary. When a plurality of wiring layers are formed in the wiring substrate 30, an insulation layer is arranged between adjacent wiring layers. The wiring layers and vias formed in the insulation layers electrically connect the mounting pads 31 and the connection pads 32. For example, a build-up core substrate, which includes a core substrate, or a coreless substrate, which does not include a core substrate, may be used as the wiring substrate 30.

The connection members 40 are connected to the connection pads 32 of the wiring substrate 30.

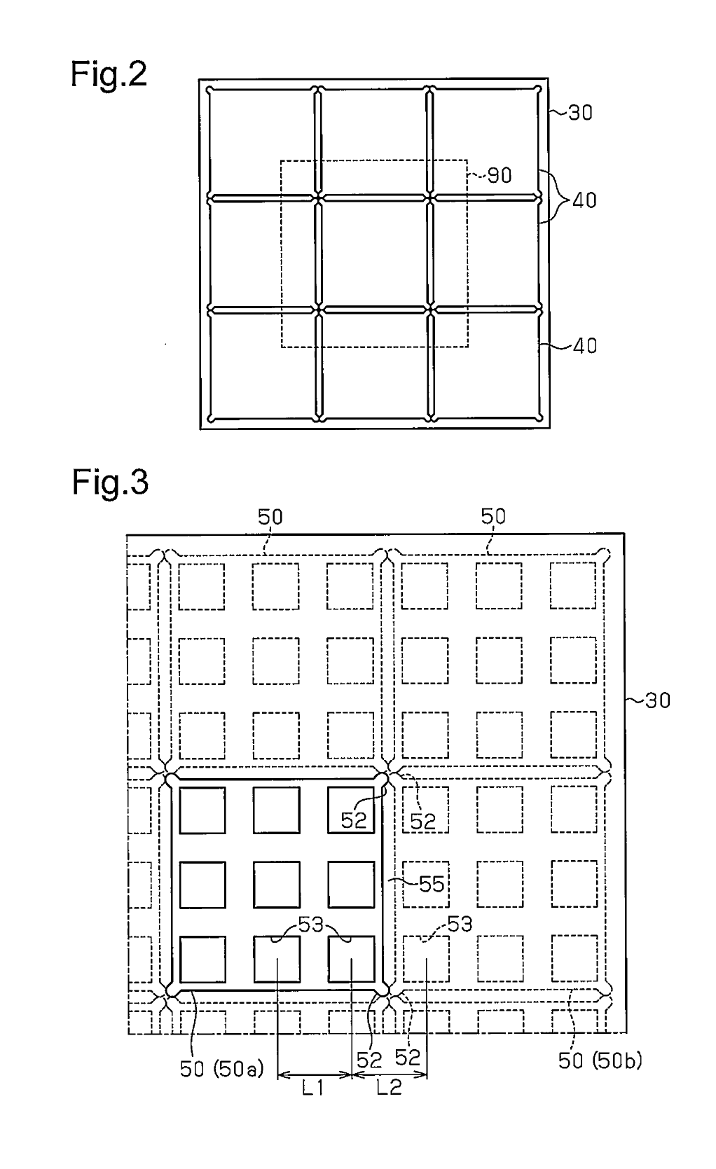

As illustrated in FIG. 2, the wiring substrate 30 is tetragonal in a plan view. FIG. 2 schematically illustrates the outlines of the semiconductor element 90, the wiring substrate 30, and the connection members 40. Components contained in the semiconductor element 90, the wiring substrate 30, and the connection members 40 are not illustrated in FIG. 2. The semiconductor element 90 (indicated by broken lines) is mounted on a central area of the wiring substrate 30. The connection members 40 are arranged on the second surface 30b (lower surface) of the wiring substrate 30. The semiconductor package 20 of the present embodiment includes nine connection members 40 arranged in a matrix along the second surface 30b of the wiring substrate 30.

As illustrated in FIG. 1, each connection member 40 includes a holding member 50 and a plurality of connection terminals 60. The material of the holding members 50 is an insulative resin, such as a liquid crystal polymer (LCP) resin. The holding member 50 includes a main body 51 and a plurality of projections 52.

As illustrated in FIG. 3, the main body 51 is tetragonal. To clarify the relationship of adjacent holding members 50, FIG. 3 illustrates one of the holding members 50 in solid lines and other holding members 50 in broken lines. Each projection 52 projects outward from a vertex of the main body 51 along a diagonal line. Thus, the holding member 50 of the present embodiment includes four projections 52. As illustrated in FIG. 1, the main body 51 includes a first surface 51a (upper surface as viewed in the drawing) and a second surface 51b (lower surface as viewed in the drawing) that are opposed to each other. Each projection 52 extends along a side surface 51c of the main body 51 from the second surface 51b to the first surface 51a of the main body 51, that is, in the heightwise direction of the main body 51. The main body 51 includes a plurality of through holes 53 extending from the first surface 51a to the second surface 51b. As illustrated in FIG. 5, each through hole 53 is defined by a tetragonal inner wall in the main body 51. In the second surface 51b of the main body 51, an open end of each through hole 53 includes a step 53a.

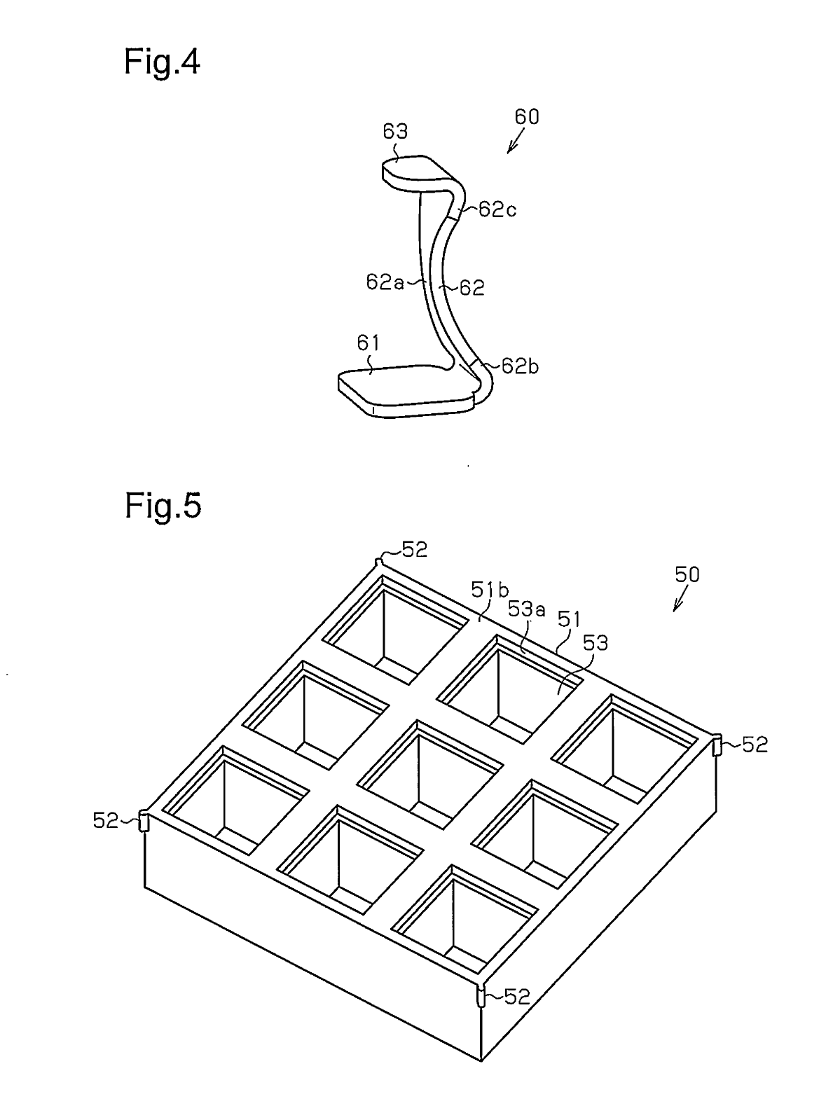

As illustrated in FIG. 4, the connection terminal 60 includes a connection portion 61 (first connection portion), an elastic portion 62, and a connection portion 63 (second connection portion). The connection portions 61 and 63 are flat and opposed to each other. The elastic portion 62 couples the connection portions 61 and 63. The elastic portion 62 is curved toward a gap between the connection portions 61 and 63. In the elastic portion 62, the width of a central portion 62a is smaller than the widths of two end portions 62b and 62c.

The connection terminal 60 is an elastic and conductive member. The material of the connection terminal 60 may be, for example, copper (Cu) or a copper alloy. A plating layer of nickel (Ni) or the like is formed on a surface of the connection terminal 60. A lower surface of the connection portion 61 defines a connection surface 61a. A plating layer of gold (Au) or the like is formed on the connection surface 61a. Such plating improves the solder wettability and the connection reliability.

The connection terminal 60 is formed, for example, by using a pressing machine to bend a metal plate having a predetermined shape. The thickness of the connection terminal 60 is 0.04 to 1.00 mm. The connection terminal 60 may be formed by etching a metal plate into a predetermined shape and then bending the etched metal plate.

The connection portion 63 is electrically and mechanically connected to one of the connection pads 32 of the wiring substrate 30. In the present embodiment, solder 71 connects the connection portions 63 and the connection pads 32. The solder 71 is one example of a connecting material. The connection portions 63 and the connection pads 32 may be connected with a conductive material, such as a conductive resin paste (e.g., silver (Ag) paste). The connection portions 63 and the connection pads 32 may be connected and bonded by gold (Au) and indium (In).

The connection portion 61 is inserted into one of the through holes 53 in the holding member 50 (main body 51) and fixed to the main body 51 of the holding member 50. As illustrated in FIG. 5, each through hole 53 includes the step 53a at the open end of the second surface 51b of the main body 51. The step 53a is formed in correspondence with the size and the thickness of the connection portion 61, for example, so that the depth of the step 53a is greater than the thickness of the connection portion 61. Therefore, the connection portion 61 of the connection terminal 60 is arranged so that the second surface 51b of the main body 51 projects beyond the connection surface 61a of the connection portion 61. The connection portion 61 is fixed to the step 53a, for example, with an adhesive agent. For example, an ultraviolet curable adhesive agent, a thermosetting adhesive agent, or the like, may be used as the adhesive agent. In this manner, the holding member 50 (main body 51) holds the connection terminals 60.

As illustrated in FIG. 1, the connection surface 61a of each connection portion 61 is exposed from the second surface 51b of one of the holding members 50 (main body 51). A solder ball 83 is formed on the connection surface 61a of each connection portion 61. The solder ball 83 is used to connect the connection terminal 60 to the motherboard MB. The solder ball 83 may be formed from a material having a melting point that is lower than the solders 71, which connects the connection portions 63 and the connection pads 32. In other words, the connection terminals 60 are connected to the connection pads 32 of the wiring substrate 30 using a material (high melting point material) having a higher melting point than the solder balls 83, which connect the connection portions 61 and the motherboard MB.

As illustrated in FIG. 3, the size of each projection 52 corresponds to the distance between adjacent holding members 50. The projections 52 are set so that the through holes 53 of adjacent holding members 50 are located at equal intervals.

For example, the connection terminals 60, such as that illustrated in FIG. 4, are inserted into the through holes 53 that are laid out in columns of a matrix in the main body 51. As illustrated in FIG. 1, each connection terminal 60 is connected to one of the connection pads 32 of the wiring substrate 30. The connection pads 32 of the wiring substrate 30 are arranged at the same pitch in a matrix. Thus, the through holes 53 in one of the same holding member 50 have a pitch L1 (distance between the centers of the through holes 53, that is, interval of the connection terminals 60) that is set to be the same as the pitch of the connection pads 32 arranged on the wiring substrate 30. In two adjacent holding members 50 (reference characters 50a and 50b are given in FIG. 3), a pitch L2 between the through hole 53 of the holding member 50a and the through hole 53 of the holding member 50b is the same as the pitch L1 between the through holes 53 of the holding member 50a. Therefore, in FIG. 3, the through holes 53 are arranged at the same interval in a lateral direction. FIG. 3 illustrates the layout of the holding members 50 in the lateral direction. The holding members 50 are laid out in the same manner in the longitudinal direction.

The operation of the semiconductor device 10 will now be described.

The semiconductor device 10 includes the wiring substrate 30, on which the semiconductor element 90 is mounted, and the connection members 40, which are connected to the wiring substrate 30. Each connection member 40 includes the holding member 50 and the connection terminals 60. The holding member 50 holds the connection portion 61 of each connection terminal 60. The connection portion 63 of each connection terminal 60 is connected by the solder 71 to one of the connection pads 32 on the second surface 30b of the wiring substrate 30.

Each connection terminal 60 is an elastic and conductive member. The connection terminals 60 follow the uneven distance between the wiring substrate 30 and the holding members 50, that is, between the wiring substrate 30 and the connection portions 61. Thus, when the motherboard MB warps or twists due to heat or the like, the holding members 50 move independently from one another in accordance with changes in the form of the motherboard MB. Therefore, stress applied to the solder ball 83 is reduced, and breaking solder defect is reduced.

As illustrated in FIG. 3, the projections 52 of each holding member 50 each contact a projection 52 of at least one adjacent holding member 50. This forms a gap 55 between two adjacent holding members 50. The gap 55 allows the two adjacent holding members 50 to be inclined relative to each other. Therefore, stress applied to the solder ball 83 is reduced, and breaking solder defect is reduced.

In the same manner, the holding members 50 change positions when the semiconductor package 20 is mounted on the motherboard MB that is, for example, warped. This ensures the connection of the solder balls 83 of the semiconductor package 20 to the motherboard MB that is warped. Thus, defective connections are reduced, and the yield is increased. This reduces the number of steps when mounting the semiconductor package 20 and eliminates the need for temperature management, which would be performed to avoid warping of the motherboard MB.

Each connection terminal 60 is an elastic and conductive member. The connection terminals 60 allow relative movement of the wiring substrate 30 and the holding members 50, that is, relative movement of the wiring substrate 30 and the connection portions 61, in a direction orthogonal to the second surface 30b of the wiring substrate 30. The connection terminals 60 also allow relative movement of the wiring substrate 30 and the holding members 50 (connection portions 61) in a direction parallel to the second surface 30b of the wiring substrate 30.

The procedures for manufacturing the connection member 40 will now be described.

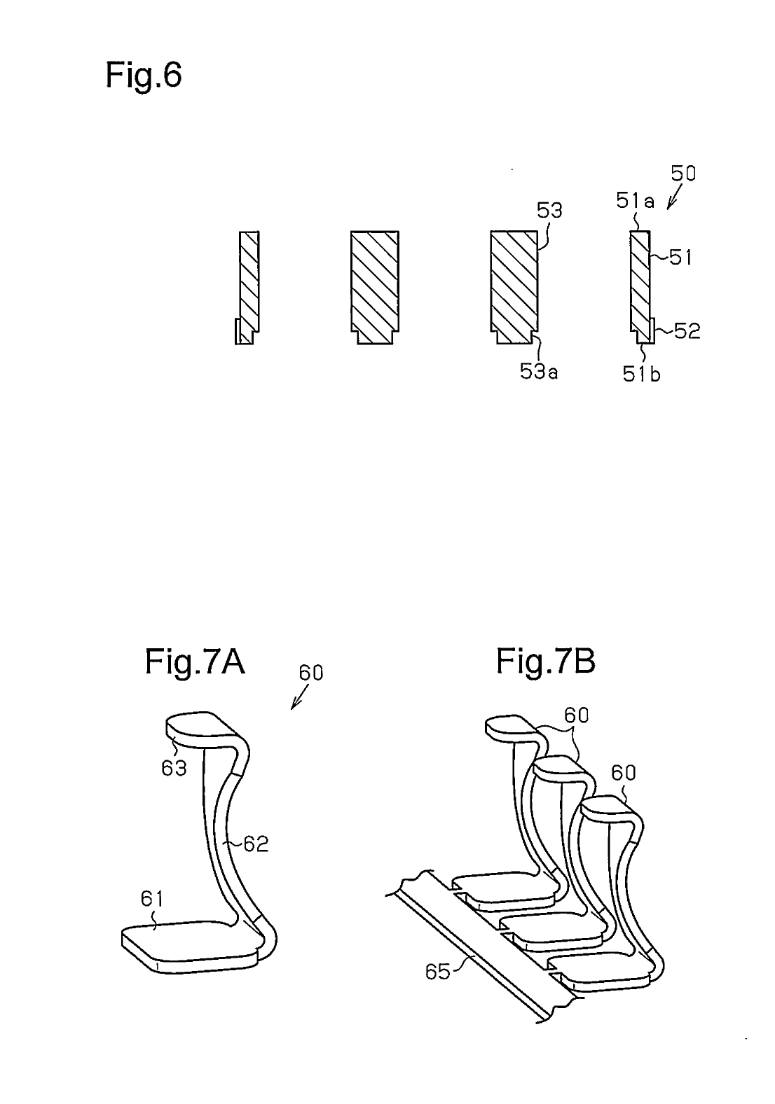

As illustrated in FIG. 6, the holding member 50 is formed. For example, the holding member 50 may be formed by molding resin.

As illustrated in FIG. 7A, the connection terminal 60 is formed. A metal plate undergoes mechanical processing, such as pressing or laser cutting, or chemical processing, such as etching, to obtain a predetermined shape. The metal plate is then bent to form the connection terminal 60.

As illustrated in FIG. 7B, a plurality of the connection terminals 60 may be simultaneously formed connected by a lead frame 65. Then, the connection terminals 60 may each be separated from the lead frame 65.

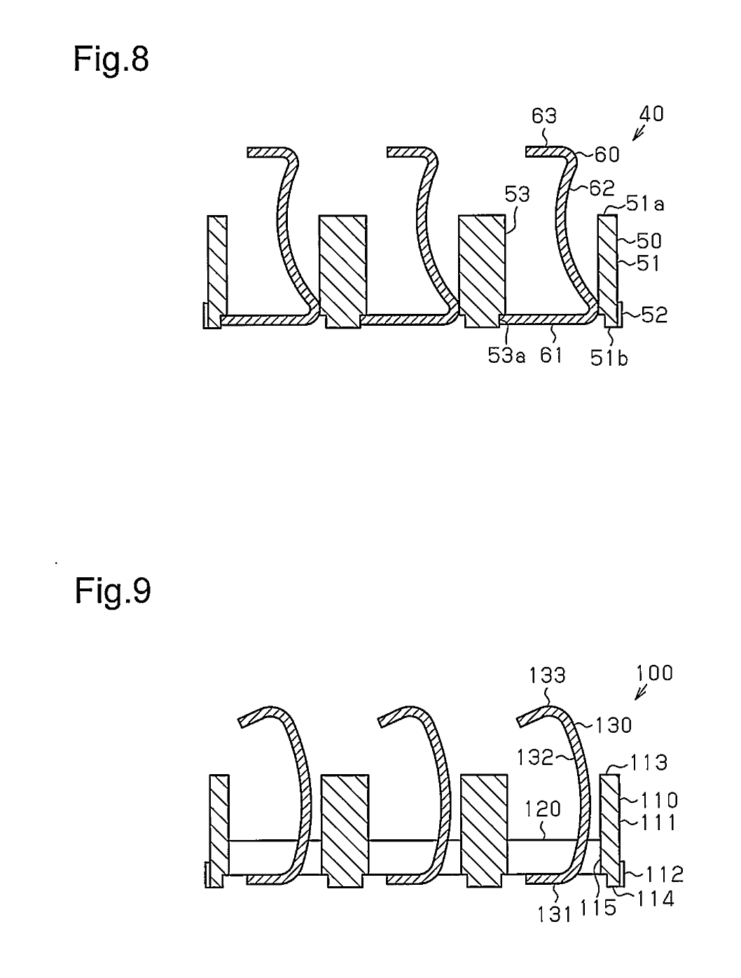

As illustrated in FIG. 8, the connection terminals 60 are fixed to the holding member 50. For example, an ultraviolet curable adhesive agent is applied to each step 53a of the holding member 50, and the connection portion 63 of a connection terminal 60 is inserted into each through hole 53 of the holding member 50. When the connection portions 61 contact the steps 53a, the adhesive agent is cured. This fixes the connection portions 61 of the connection terminals 60 to the steps 53a. The holding member 50 holds the connection terminals 60. Alternatively, the connection terminals 60 may be press-fitted and fixed to the holding member 50. For example, the connection portion 61 of each connection terminal 60 is set to be larger than the through holes 53 of the holding member 50. By press-fitting the connection portion 61 to the through hole 53, the connection terminal 60 is fixed to the holding member 50. Alternatively, a section including the connection portion 61 and the end portion 62b of the elastic portion 62 may be set to be larger than the through hole 53. By press-fitting the section, the connection terminal 60 is fixed to the holding member 50.

Accordingly, the present embodiment has the advantages described below.

(1) The semiconductor device 10 includes the wiring substrate 30, on which the semiconductor element 90 is mounted, and the connection members 40, which are connected to the wiring substrate 30. Each connection member 40 includes the holding member 50 and the connection terminals 60. The holding member 50 holds the connection portion 61 of each connection terminal 60. The solder 71 connects the connection portion 63 of each connection terminal 60 and one of the connection pads 32 of the second surface 30b of the wiring substrate 30.

The wiring substrate 30 of the semiconductor package 20 is mounted on the motherboard MB using the elastic connection terminals 60. Heat and stress changes the shape of each connection terminal 60. This reduces the stress applied to the solder that connects each connection terminal and the motherboard MB. Consequently, breakage of the solder (solder ball 83) may be reduced thereby limiting decreases in the reliability.

(2) When warping or the like occurs in the motherboard MB, the holding members 50 move independently from one another in accordance with the shape of the mounting substrate MB. The solder ball 83 of each connection member 40 contacts one of the pads of the motherboard MB. This ensures the connection of each connection member 40 to the motherboard MB. Thus, the semiconductor package 20 is connected to the motherboard MB even when the motherboard MB is warped. This limits defective connections and improves the yield.

(3) The solder balls 83, which are located on distal ends of the connection terminals 60, are formed from a material, the melting point of which is lower than that of the solder 71 connecting the connection terminals 60 and the wiring substrate 30. Thus, the heat of a reflow furnace or the like does not melt the solder 71 when mounting the semiconductor package 20 on the motherboard MB. This facilitates the mounting of the semiconductor package 20 on the motherboard MB. Additionally, the semiconductor package 20 may be easily removed from the motherboard MB when applying enough heat to melt the solder 71.

It should be apparent to those skilled in the art that the present invention may be embodied in many other specific forms without departing from the scope of the invention. Particularly, it should be understood that the present invention may be embodied in the following forms.

The above embodiment may be modified as described below. Reference characters may be deleted for components that are the same as corresponding components of the above embodiment. Such elements will not be described in detail.

In the above embodiment, the structure of the connection member 40 and the materials and the shapes of the holding member 50 and the connection terminal 60 may be modified.

For example, as illustrated in FIG. 9, a connection member 100 includes a holding member 110, a plurality of holding pieces 120, and a plurality of connection terminals 130.

In the same manner as the holding member 50, the holding member 110 includes a main body 111 and an adjustment portion 112. The main body 111 includes through holes 115 extending from a first surface 113 to a second surface 114. The holding member 110 is formed by metal. The material of the holding member 110 may be, for example, aluminum, an aluminum alloy, copper, a copper alloy, or the like.

Each connection terminal 130 includes a connection portion 131, an elastic portion 132, and a connection portion 133. Each connection terminal 130 is generally C-shaped in a side view.

Each connection terminal 130 is fixed to one of the holding pieces 120. The holding pieces 120 each have a rectangular cross-section. Each holding piece 120 is fixed to one of the through holes 115 of the holding member 110. The holding piece 120 is, for example, an insulator formed from an epoxy resin or the like. The holding member 110, which is formed from metal, may be connected to, for example, ground. This limits noise that enters the connection terminals 130 and allows the connection terminals 130 to transmit high frequency signals.

The connection terminals 130, which are fixed to the insulative holding pieces 120, may be applied to a resin holding member. In this case, the holding pieces 120 may be fixed to the holding member by performing press-fitting or fusing or by applying an adhesive agent.

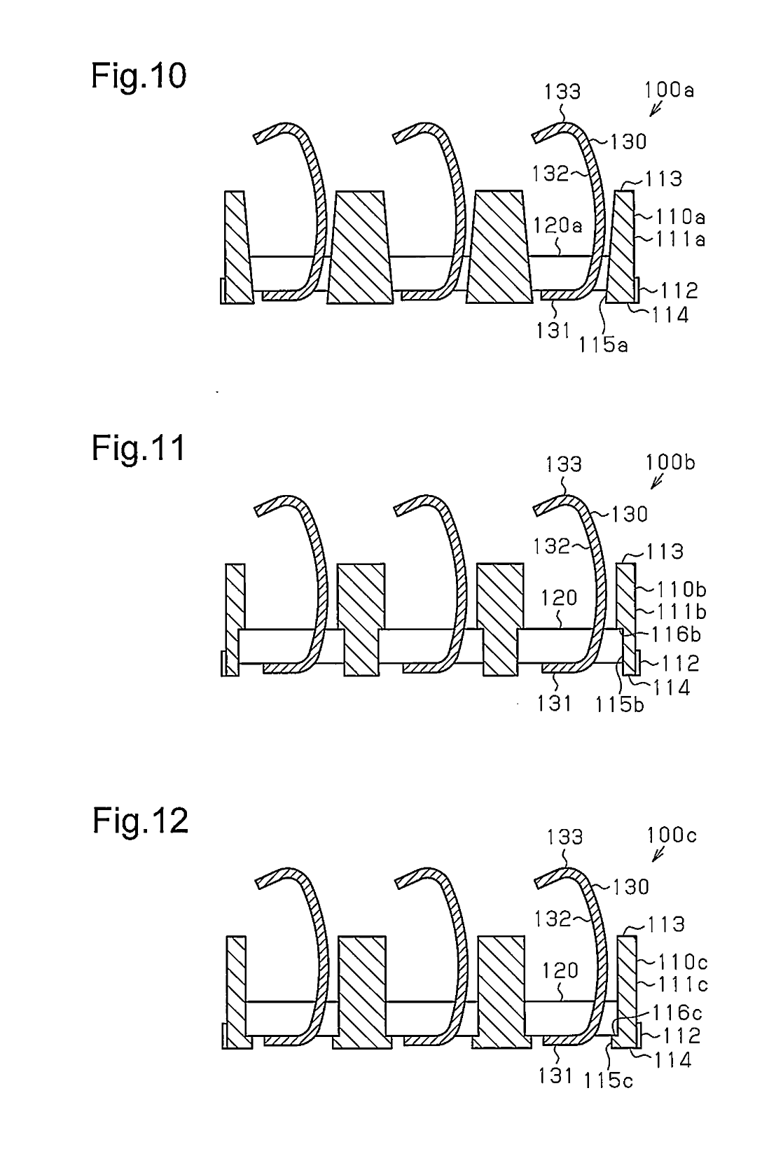

As illustrated in FIG. 10, a connection member 100a includes a holding member 110a, a plurality of holding pieces 120a, and the connection terminals 130. In the same manner as the holding member 110 illustrated in FIG. 9, the holding member 110a includes a main body 111a and the adjustment portion 112. The main body 111a includes a plurality of through holes 115a extending from a first surface 113 to a second surface 114. Each through hole 115a is gradually tapered from the first surface 113 to the second surface 114. Each connection terminal 130 is fixed to one of the holding pieces 120a. The holding pieces 120a each have a rectangular or trapezoidal cross-section. Each holding piece 120a is press-fitted to one of the through holes 115a.

As illustrated in FIG. 11, a connection member 100b includes a holding member 110b, the holding pieces 120, and the connection terminals 130. In the same manner as the holding member 110 illustrated in FIG. 9, the holding member 110b includes a main body 111b and the adjustment portion 112. The main body 111b includes a plurality of through holes 115b extending from a first surface 113 to a second surface 114. Each through hole 115b includes a step 116b so that the through hole 115b has an opening size in the first surface 113 that is smaller than an opening size in the second surface 114. Each holding piece 120 is inserted into the through hole 115b from the second surface 114 and fixed (positioned) by the step 116b.

As illustrated in FIG. 12, a connection member 100c includes a holding member 110c, the holding pieces 120, and the connection terminals 130. In the same manner as the holding member 110 illustrated in FIG. 9, the holding member 110c includes a main body 111c and the adjustment portion 112. The main body 111c includes a plurality of through holes 115c extending from a first surface 113 to a second surface 114. Each through hole 115c includes a step 116c so that the through hole 115c has an opening size in the first surface 113 that is larger than an opening size in the second surface 114. Each holding piece 120 is inserted into the through hole 115c from the first surface 113 and fixed (positioned) by the step 116c.

The shape of the connection terminal 60 may be modified.

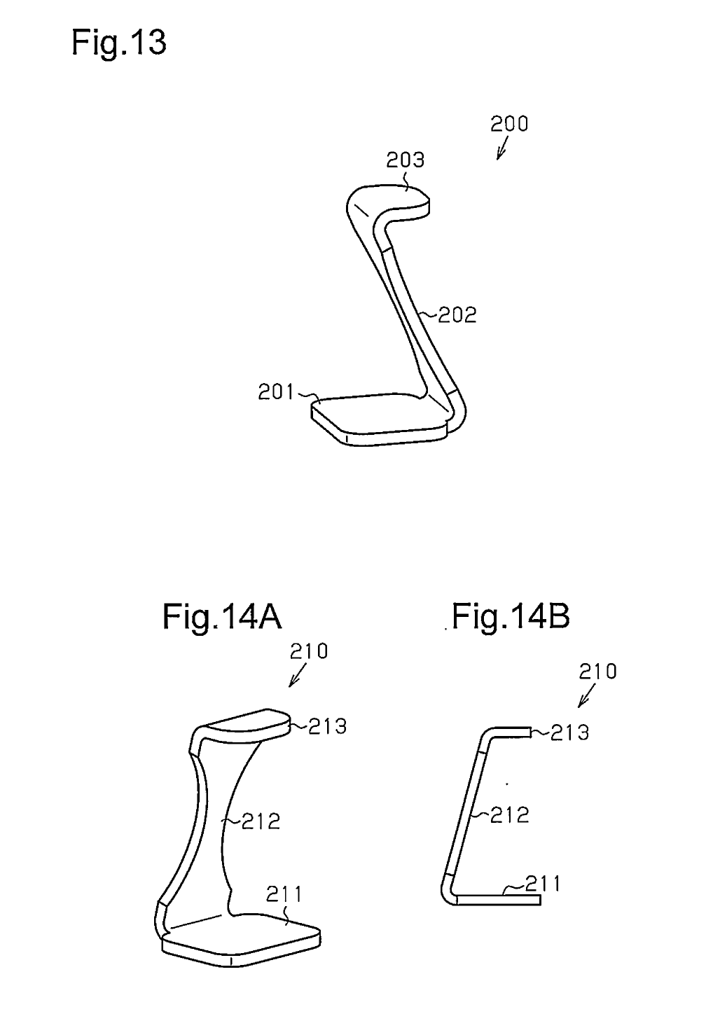

For example, as illustrated in FIG. 13, a connection terminal 200 includes a connection portion 201, an elastic portion 202, and a connection portion 203. The connection portions 201 and 203 are flat and opposed to each other. The elastic portion 202 is flat and couples the connection portions 201 and 203. In the connection terminal 200, the connection portions 201 and 203 extend in opposite directions from portions where the elastic portion 202 is connected to the connection portions 201 and 203.

As illustrated in FIGS. 14A and 14B, a connection terminal 210 includes a connection portion 211, an elastic portion 212, and a connection portion 213. The connection portions 211 and 213 are flat and opposed to each other. The elastic portion 212 is flat and couples the connection portions 211 and 213. In the connection terminal 210, the connection portions 211 and 213 extend in the same direction from portions where the elastic portion 212 is connected to the connection portions 211 and 213, respectively.

The connection terminal may be cylindrical.

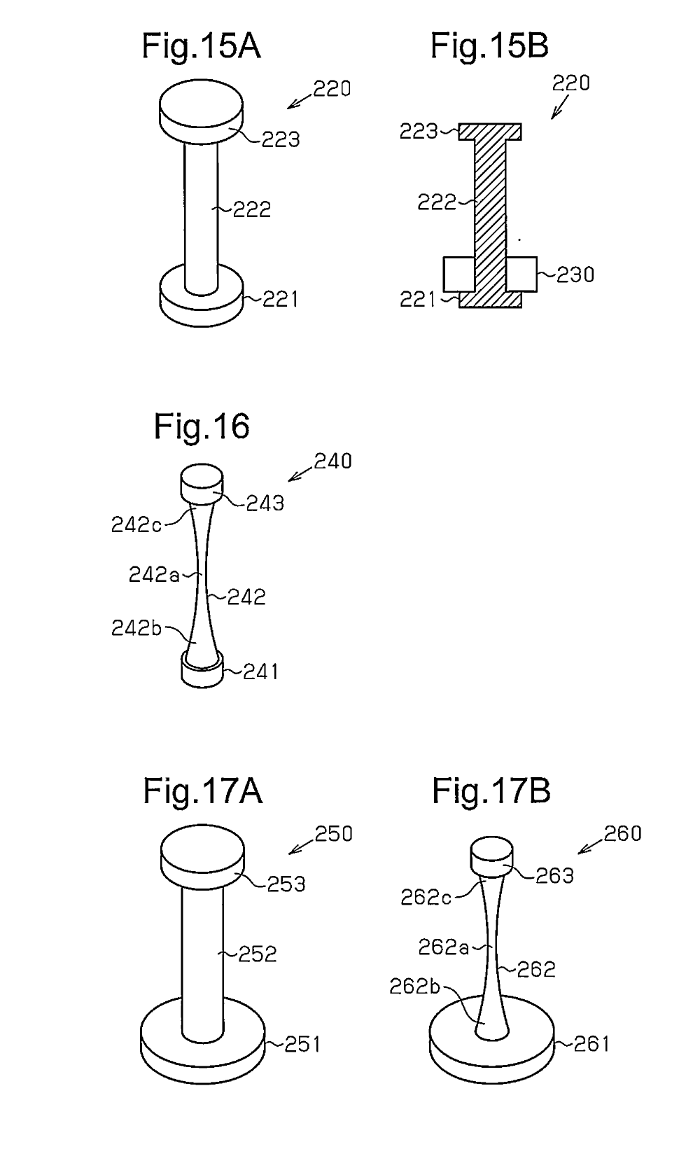

For example, as illustrated in FIG. 15, a connection terminal 220 includes discoid connection portions 221 and 223 and a cylindrical elastic portion 222, which couples the connection portions 221 and 223. The elastic portion 222 is bendable and is expanded and contracted in the axial direction. For example, as illustrated in FIG. 15B, in the connection terminal 220, the holding piece 230 is fixed to the elastic portion 222, and the holding piece 230 is fixed to a holding member to form a connection member.

As illustrated in FIG. 16, a connection terminal 240 may be formed. The connection terminal 240 includes discoid connection portions 241 and 243 and an elastic portion 242, which couples the connection portions 241 and 243. In the elastic portion 242, a central portion 242a is thinner than two end portions 242b and 242c. The connection terminal 240 may be fixed to a holding member using a holding piece in the same manner as FIG. 15B to form a connection member.

As illustrated in FIG. 17A, a connection terminal 250 includes discoid connection portions 251 and 253 and a cylindrical elastic portion 252, which couples the connection portions 251 and 253. The connection portion 251 is larger than the connection portion 253. In the same manner as the above embodiment, the connection terminal 250 may be directly fixed to a holding member at the connection portion 251 to form a connection member.

In the same manner, a connection terminal 260 illustrated in FIG. 17B includes discoid connection portions 261 and 263 and an elastic portion 262, which couples the connection portions 261 and 263. In the elastic portion 262, a central portion 262a is thinner than two end portions 262b and 262c. The connection portion 261 is larger than the connection portion 263. In the same manner as the above embodiment, the connection terminal 260 may be directly fixed to a holding member at the connection portion 261 to form a connection member.

In each embodiment, as illustrated in FIG. 3, the main body 51 includes the projections 52 at the four vertices. However, the position and the shape of each projection 52 are not limited as illustrated in the embodiment. For example, a side surface of the main body 51 may include a projection. Each side surface of the main body 51 may include a plurality of projections.

In each embodiment, the interval of the connection terminals 60 is set when the projections 52 of the holding members 50 are in contact with one another (e.g., illustrated in FIG. 3). However, the interval may be set when the projection 52 is in contact with the main body 51 of the adjacent holding member 50.

In each embodiment, as illustrated in FIG. 3, the holding member 50 holds the connection terminals 60 laid out in three rows and three columns. However, the number of the connection terminals 60 held by the holding member 50 may be changed, such as to two rows and two columns, four rows and four columns, or five rows and five columns. Alternatively, the holding member may hold the connection terminals in a number of rows that differ from the number of columns, such as three rows and four columns or four rows and six columns.

The present examples and embodiments are to be considered as illustrative and not restrictive, and the invention is not to be limited to the details given herein, but may be modified within the scope and equivalence of the appended claims.

1. A semiconductor package comprising:
a wiring substrate including a first surface and a second surface that are opposed to each other, a plurality of mounting pads arranged on the first surface, and a plurality of connection pads arranged on the second surface; and
a plurality of connection members respectively connected to the connection pads, wherein
each of the connection members includes
a holding member opposing the second surface of the wiring substrate, and
a plurality of elastic and conductive connection terminals, wherein each of the connection terminals includes a first end and a second end, the first end is held by the holding member so that the first end is exposed from a surface of the holding member that is located at a side opposite to the wiring substrate, and the second end is connected to a corresponding one of the connection pads.

2. The semiconductor package according to claim 1, further comprising a plurality of connecting materials that have a high melting point, wherein the connecting materials connect the second ends of the connection terminals and the connection pads, respectively.

3. The semiconductor package according to claim 1, further comprising
a plurality of solder balls respectively arranged on the first ends of the connection terminals, and
a plurality of connecting materials that connect the second ends of the connection terminals and the connection pads, respectively, wherein
the connecting materials include a material having a higher melting point than the solder balls.

4. The semiconductor package according to claim 1, wherein the holding member holds the connection terminals through an insulator.

5. The semiconductor package according to claim 4, wherein the holding member is formed from a metal.

6. The semiconductor package according to claim 1, wherein the connection terminals are formed by bending a metal plate.

7. The semiconductor package according to claim 6, wherein each of the connection terminals includes
a first connection portion and a second connection portion that are flat and parallel to each other, and
an elastic portion that couples the first connection portion and the second connection portion.

8. The semiconductor package according to claim 1, wherein the connection terminals are cylindrical.
